(19) United States
(12) Patent Application Publication
(10) Pub. No.: US 2010/0101840 A1
(43) Pub. Date: Apr. 29, 2010

(54) APPLICATION OF A SELF-ASSEMBLED MONOLAYER AS AN OXIDE INHIBITOR

(75) Inventors: Andreas HAMPP, Santa Barbara, CA (US); Christine COBB, Goleta, CA (US)

Correspondence Address: Pillsbury Winthrop Shaw Pittman LLP;(Raytheon SAS), P.O. Box 10500, McLean, VA, 22102, US

(73) Assignee: RAYTHEON COMPANY, Waltham, MA (US)

(21) Appl. No.: 12/260,471

(22) Filed: Oct. 29, 2008

(51) Int. Cl. H05K 1/09; B05D 5/12; H05K 3/36

(52) U.S. Cl. 174/257; 427/123; 29/830

(57) ABSTRACT

An embodiment is directed to a method of forming a self assembled monolayer to reduce formation of an oxide. The method includes applying an inhibitor to a substrate including conductive contacts and processing the substrate and inhibitor to form the self assembled monolayer.

### BACKGROUND

This disclosure relates generally to the field of self-assembled monolayers and, more specifically, to the application of a self-assembled monolayer to a substrate containing a contact metal, e.g., indium, to prevent oxide formation when peripheral electronic components are connected.

Self assembled monolayers (SAMs) are surfaces consisting of a single layer of molecules on a substrate. Rather than having to use a technique such as chemical vapor deposition or molecular beam epitaxy to add molecules to a surface (often with poor control over the thickness of the molecular layer), self assembled monolayers can be prepared simply by adding a solution of the desired molecule onto the substrate surface and washing off the excess.

Flip chip hybridization is a microelectronics packaging and assembly process which directly connects an individual chip (e.g., a sensor device) to a substrate, e.g., a readout integrated circuit (ROIC), eliminating the need for peripheral wirebonding. Electrical connections are made between the two parts using interconnect bumps consisting of a conductive material. One type of conductive interconnect bump that may be used for direct connection of certain active devices to the substrate is an indium bump. However, the use of indium poses a problem requiring special processing, since it readily oxides in air. Once formed, an oxide layer formed on indium is difficult to break.

Currently, one technique to remove this oxide layer is a mechanical scrubbing process where two indium bumps are rubbed against each other until the oxide layer breaks. Such conventional removal of indium oxide from the conductive interconnects often results in harmful mechanical stresses being imposed on the chip contacts that may have an adverse impact on manufacturing yields. Another technique to remove oxidation is by using a cleaning agent, such as a flux. Fluxes can be categorized as either corrosive and noncorrosive. For electrical devices, the fluxes should be noncorrosive. The use of fluxes also requires the application of a solvent to remove contaminants from the soldered connection. The solvents must be nonconductive and noncorrosive and used in a manner that keeps dissolved flux residue from “contact” surfaces. Any flux remaining in the joint corrodes the connection and creates a defective circuit.

### SUMMARY

In accordance with one embodiment of this disclosure, a method of forming a self assembled monolayer to reduce formation of an oxide is disclosed. The method includes applying an inhibitor to a substrate including conductive contacts and processing the substrate and inhibitor to form the self assembled monolayer.

In accordance with one embodiment of this disclosure, a device manufacturing method is disclosed. The method includes providing a first electronic circuit comprising a first plurality of metal contacts thereon; providing a second electronic circuit comprising a second plurality of metal contacts thereon; forming a self assembled monolayer between the first plurality of metal contacts and the second plurality of metal contacts; and conductively connecting the first plurality of metal contacts and the second plurality of metal contacts together.

These and other features and characteristics, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various Figures. It is to be expressly understood, however, that the drawings are for the purpose of illustration and description only and are not intended as a definition of the limits of claims. As used in the specification and in the claims, the singular form of “a”, “an”, and “the” include plural referents unless the context clearly dictates otherwise.

### BRIEF DESCRIPTION OF THE DRAWINGS

FIG. 1 shows an exemplary method for applying the self-assembled monolayer inhibitor in accordance with an embodiment.

FIG. 2 shows substrate with the applied self-assembled monolayer in accordance with an embodiment.

FIGS. 3a and 3b show experimental results of indium oxide formation growth without application of the self-assembled monolayer inhibitor and with the inhibitor.

FIGS. 4a and 4b show results of imaging by a scanning electron microscope for both an untreated sample and a sample treated with an indium oxide inhibitor solution.

### DETAILED DESCRIPTION

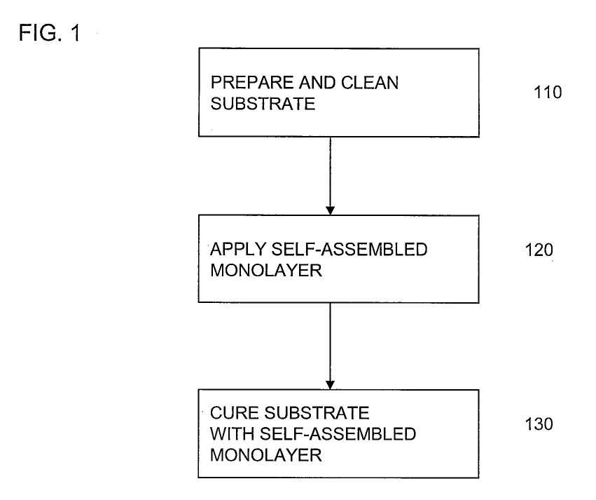

FIG. 1 shows an exemplary method for applying a self-assembled monolayer inhibitor. First, a substrate containing conductive bumps may be prepared and cleaned 110 by applying a solution of acid, e.g., hydrochloric acid (5 vol %), in deionized water. The substrate may then be rinsed with one or more of toluene, acetone, methanol and isopropanol, and dried by applying an inert gas, e.g., nitrogen gas, to the substrate.

Any pre-existing oxide on the contact, e.g., indium oxide, may be removed from the substrate by an etch process. The substrate may be etched by immersion in an acid solution, e.g., a hydrochloric acid and water solution, for about 1 minute. The substrate may then be rinsed in deionized water and then rinsed with acetone. The substrate may be dried in an inert gas, e.g., nitrogen gas.

The self-assembled monolayer inhibitor is then applied to the substrate 120, which protects against oxide growth on the substrate. In one embodiment, the inhibitor may be a solution of 1 mM of benzotriazole (C₆H₅N₃) or octadecanethiol (C₁₈H₃₈S) mixed with ethanol. The substrate is immersed in the inhibitor solution for about 60 minutes. Once the substrate has been applied with the inhibitor solution, the substrate may be rinsed with isopropanol and dried by the application of nitrogen gas.

The self-assembled monolayer may then be cured 130 to the substrate by heating the substrate at 200C for 5 minutes in air.

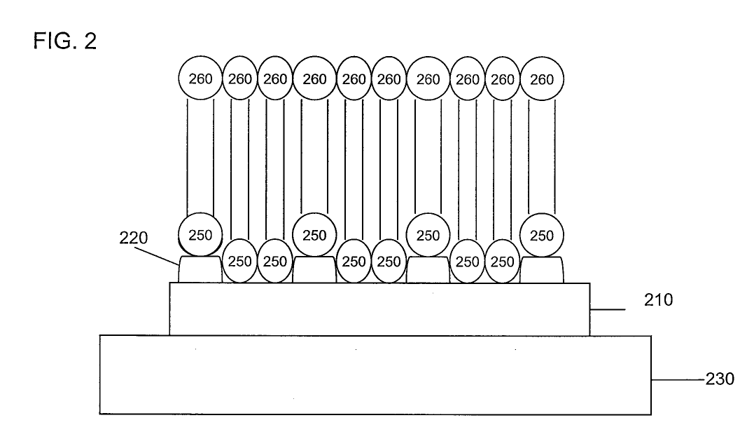

FIG. 2 shows an exemplary semiconductor chip with the applied self-assembled monolayer in accordance with an embodiment. Chip 210 includes one or more indium bumps 220 mounted onto substrate 230. Indium bumps 220 may perform a plurality of functions for the chip including provide a conductive path from chip 210 to another semiconductor chip. Moreover, indium bumps 220 may provide a thermally conductive path to carry heat away from chip 210 , as well as providing mechanical mounting of chip 210 to substrate 230. Further, indium bumps 220 provide a spacer, thus preventing electrical contact between hip 210 and substrate 230 conductors. Self-assembled monolayer 240 includes head group 250 and tail group 260. Head group 250 bonds to substrate 230 due to its high affinity to the substrate and tail group 260 forms away from substrate 230.

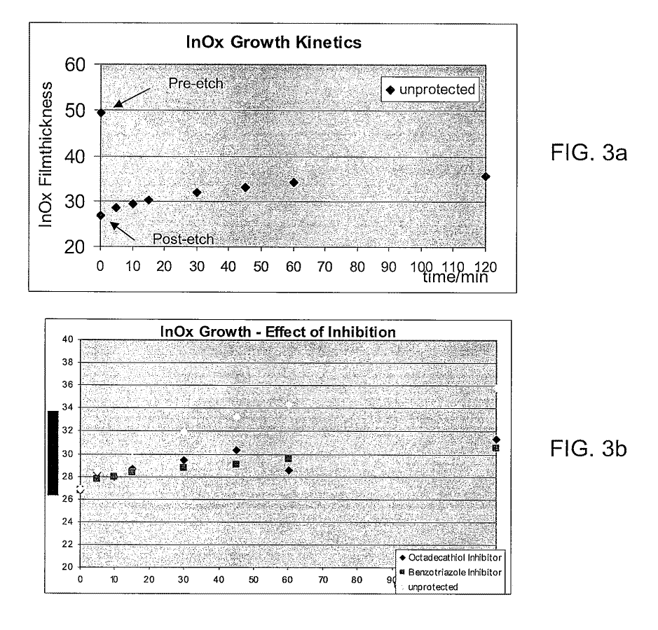

FIG. 3a and 3b show experimental results of indium oxide formation growth without application of the self-assembled monolayer inhibitor and with the inhibitor. In the experimental set-up, a sample including indium bumps with no inhibitor solution is compared with a sample having the inhibitor solution. Both inhibitor solutions, including benzotriazole and octadecanethiol mixed with ethanol, were tested. FIG. 3a shows the growth of indium oxide measured via ellipsometry over a 2 hour period in air at ambient following a 3% hydrochloric etch for the sample without the inhibitor solution. As can be seen in the figure, the indium oxide film thickness steadily increases over time. FIG. 3b shows the indium oxide growth of the untreated sample in comparison with the treated samples. As can be seen in the figure, both inhibitor solutions of benzotriazole and octadecanethiol show a measurable effect on the indium oxide formation in air at ambient conditions.

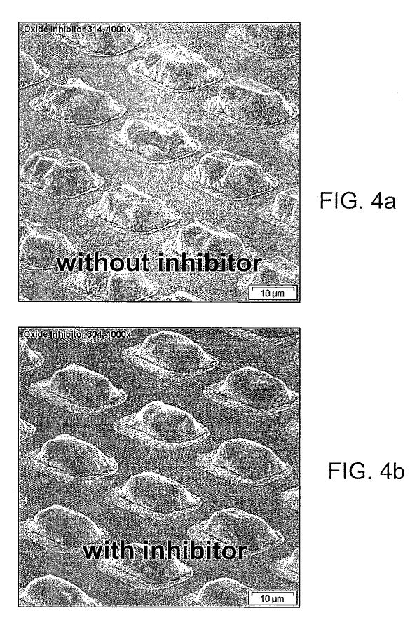

FIG. 4a and 4b show results of imaging by a scanning electron microscope for both an untreated sample and a sample treated with an indium oxide inhibitor solution. In FIG. 4a, the untreated sample was etched by immersion in a hydrochloric acid and water solution for about 1 minute. The untreated sample was then rinsed twice in deionized water and then rinsed with acetone. The untreated sample was then dried by application of nitrogen gas and then cured by heating at 200C for 5 minutes in air. As can be seen in the figure, the untreated sample show no significant changes in the indium bump shape. In FIG. 4b, the sample underwent the same process; however, the sample was subjected to an application of the indium oxide inhibitor solution after the etching step and before the curing step. As can be seen in the figure, the treated sample shows that the indium bumps are protected from indium oxide growth, and are thus enabled to reflow when baked to form a smooth, more rounded bump.

Although the above disclosure discusses what is currently considered to be a variety of useful embodiments, it is to be understood that such detail is solely for that purpose, and that the appended claims are not limited to the disclosed embodiments, but, on the contrary, is intended to cover modifications and equivalent arrangements that are within the spirit and scope of the appended claims.

We claim:

1. A method of forming a self assembled monolayer to reduce formation of an oxide, the method comprising:
applying an inhibitor to a substrate including conductive contacts; and
processing the substrate and inhibitor to form the self assembled monolayer.

2. The method of claim 1, wherein the inhibitor solution comprises either benzotriazole or octadecanethiol mixed in a solvent.

3. The method of claim 2, wherein the solvent comprises ethanol.

4. The method of claim 1, further comprising preparing the substrate by applying a cleaning solvent including one or more of toluene, acetone, methanol, and isopropanol to the substrate.

5. The method of claim 1, further comprising preparing the substrate by drying in an inert atmosphere.

6. The method of claim 5, wherein said inert atmosphere comprises nitrogen gas.

7. The method of claim 1, further comprising preparing the substrate by etching any existing oxide by an acid solution.

8. The method of claim 7, wherein said any existing oxide comprises indium oxide.

9. The method of claim 7, wherein said acid solution comprises hydrochloric acid and de-ionized water.

10. The method of claim 7, wherein the substrate is immersed in the acid solution for about 1 minute.

11. The method of claim 1, wherein the substrate is immersed in the inhibitor solution for about 60 minutes.

12. The method of claim 1, wherein the inhibitor solution comprises about 1 mM of either benzotriazole or octadecanethiol.

13. The method of claim 1, further comprising curing the substrate by baking at about 200C for about 5 minutes.

14. The method of claim 13, wherein said baking in performed in air.

15. The method of claim 1, wherein said conductive contacts comprise indium.

16. A device manufacturing method, comprising:
providing a first electronic circuit comprising a first plurality of metal contacts thereon;
providing a second electronic circuit comprising a second plurality of metal contacts thereon;
forming a self assembled monolayer between the first plurality of metal contacts and the second plurality of metal contacts; and
conductively connecting the first plurality of metal contacts and the second plurality of metal contacts together.

17. The method of claim 16, wherein said forming a self assembled monolayer comprises applying an inhibitor solution to a substrate.

18. The method of claim 17, wherein one or more of said first plurality of metal contacts and said second plurality of metal contacts comprise indium.

19. The method of claim 17, wherein the inhibitor solution comprises either benzotriazole or octadecanethiol mixed in a solvent.

20. A device manufactured according to the method of claim 16, wherein the first plurality of metal contacts and the second plurality of metal contacts comprise indium, and wherein conductive connections between the first plurality of metal contacts and said second plurality of metal contacts are made so as to be essentially free of any indium oxide therebetween.
